(19) United States
(12) Patent Application Publication
(10) Pub. No.: US 2025/0260391 A1
(43) Pub. Date: Aug. 14, 2025

(54) RECONFIGURABLE MONOLITHICALLY INTEGRATED PHASE-CHANGE ATTENUATOR AND METHODS THEREOF

(71) Applicants: Tejinder Singh, Manotick (CA); Raafat Rezk Mansour, Waterloo (CA); Huawei Technologies Canada Co., Ltd., Kanata (CA)

(72) Inventors: Tejinder SINGH, Manotick (CA); Raafat Rezk Mansour, Waterloo (CA)

(21) Appl. No.: 19/189,458

(22) Filed: Apr. 25, 2025

Related U.S. Application Data
(63) Continuation of application No. PCT/CA2022/051589, filed on Oct. 26, 2022.

(51) Int. Cl. H03H 17/00; H10N 70/00; H10N 70/20

(52) U.S. Cl. CPC H03H 17/0054; H10N 70/231; H10N 70/8828

(57) ABSTRACT

A module has two portions, each portion has two units provides an analog-type attenuator-tuning approach having digital control. Each of the units includes an input, an output, three selectable conductive paths, and an input switching element for selectably connecting the unit input to the unit output via one of the three selectable conductive paths. The first and second paths have attenuation elements. The unit output of the first unit of each portion is connected to the unit input of the second unit thereof and the unit output of the via one of the three selectable conductive paths, the unit output of the first unit of each portion is connected to the unit input of the second unit thereof, and the unit output of the second unit of the first portion is connected to the unit input of the first unit of the second portion.

### CROSS-REFERENCE TO RELATED APPLICATION

The present application is a continuation of Patent Cooperation Treaty Application Serial No. PCT/CA2022/051589, entitled “RECONFIGURABLE MONOLITHICALLY INTEGRATED PHASE-CHANGE ATTENUATOR AND METHODS THEREOF,” filed on Oct. 26, 2022, the entirety of which is incorporated by reference herein.

### TECHNICAL FIELD

The present disclosure relates generally to signal attenuators for radio frequency systems, and in particular, to digitally-controlled signal attenuators.

### BACKGROUND

Variable reconfigurable radio frequency (RF) systems, including radar systems, vector modulators, full-duplex wireless systems, and automatic gain control amplifiers, require switched attenuators for signal level adjustments. It is important for circuits suitable for such variable reconfigurable RF systems to have the ability to uniformly control signal strength for their application in modern communication systems. However, unlike RF circuits used in receivers, strength-control circuits and attenuators in a pre-distortion or correction loop that are connected to a power amplifier (PA) for transmitter demand power-handling capability, linearity, and reliability for circuits used in modern communication systems. These devices have much more stringent requirements.

### SUMMARY

The present disclosure provides modules and methods for attenuators suitable for applications, including modern communications systems, requiring high linearity, low power consumption, and low temperature dependency. Some embodiments of modules and methods disclosed herein provide attenuators that preserve signal integrity while controlling the signal power. Some embodiments of modules and methods disclosed herein have a high dynamic range, low insertion loss, wide attenuation range, and wide frequency bandwidth.

According to one aspect of this disclosure, there is provided a module comprising two portions, each portion comprising a first unit and a second unit, each of the units comprising: a unit input; a unit output; a first, a second, and a third selectable conductive path, the first path comprising a first attenuation element and the second path comprising a second attenuation element; and an input switching element for selectably connecting the unit input to the unit output via one of the three selectable conductive paths; wherein the unit output of the first unit of each portion is connected to the unit input of the second unit thereof; and wherein the unit output of the second unit of the first portion is connected to the unit input of the first unit of the second portion.

In an embodiment, for each unit, signal attenuation of the second attenuation element is greater than signal attenuation of the first attenuation element.

In an embodiment, for each portion, signal attenuation of the first attenuation element of the second unit is greater than signal attenuation of the second attenuation element of the first unit.

In an embodiment, signal attenuation of the first attenuation element of the first unit of the second portion is greater than signal attenuation of the second attenuation element of the second unit of the first portion.

In an embodiment, signal attenuation of: the first attenuation element of the first unit of the first portion is 0.05 decibels (dB), the second attenuation element of the first unit of the first portion is 0.1 dB, the first attenuation element of the second unit of the first portion is 0.15 dB, the second attenuation element of the second unit of the first portion is 0.3 dB, the first attenuation element of the first unit of the second portion is 0.4 dB, the second attenuation element of the first unit of the second portion is 0.8 dB, the first attenuation element of the second unit of the second portion is 1.2 dB, and the second attenuation element of the second unit of the second portion is 2.4 dB.

In an embodiment, the module comprises a third portion, comprising a first unit and a second unit, each of the units comprising: a unit input; a unit output; a first, a second, and a third selectable conductive path, the first path comprising a first attenuation element and the second path comprising a second attenuation element; and an input switching element for selectably connecting the unit input to the unit output via one of the three selectable conductive paths; wherein the unit output of the first unit is connected to the unit input of the second unit; and wherein the unit output of the second unit of the second portion is connected to the unit input of the first unit of the third portion.

In an embodiment, for each unit of the third portion, signal attenuation of the second attenuation element is greater than signal attenuation of the first attenuation element.

In an embodiment, for the third portion, signal attenuation of the first attenuation element of the second unit is greater than signal attenuation of the second attenuation element of the first unit.

In an embodiment, signal attenuation of the first attenuation element of the first unit of the third portion is greater than signal attenuation of the second attenuation element of the second unit of the second portion.

In an embodiment, signal attenuation of: the first attenuation element of the first unit of the third portion is 3 dB, the second attenuation element of the first unit of the third portion is 6 dB, the first attenuation element of the second unit of the third portion is 9 dB, and the second attenuation element of the second unit of the third portion is 18 dB.

In an embodiment, the module comprises one or more additional portions, each additional portion comprising a first unit and a second unit, each of the units comprising: a unit input; a unit output; a first, a second, and a third selectable conductive path, the first path comprising a first attenuation element and the second path comprising a second attenuation element; and an input switching element for selectably connecting the unit input to the unit output via one of the three selectable conductive paths; wherein the unit output of the first unit is connected to the unit input of the second unit.

In an embodiment, each of the input switching elements is a single pole three-throw switch.

In an embodiment, each of the input switching elements comprises a phase-change material.

In an embodiment, the phase-change material comprises germanium telluride.

In an embodiment, each of the input switching elements comprises four control pads and two shared pads for control and biasing.

In an embodiment, each of the units further comprises an output switching element connected to the three selectable conductive paths and the unit output for selectably connecting one of the three selectable conductive paths and the unit output.

In an embodiment, each of the output switching elements is a single pole three-throw switch.

In an embodiment, each of the output switching elements comprises a phase-change material.

In an embodiment, the phase-change material comprises germanium telluride.

In an embodiment, each of the output switching elements comprises four control pads and two shared pads for control and biasing.

In an embodiment, each of the first attenuation elements and each of the second attenuation elements comprise bridged-T networks.

In an embodiment, the module comprises one or more amplifiers between each of the portions.

In an embodiment, the module comprises one or more matching networks between each of the portions.

According to another aspect of this disclosure, there is provided a method comprising the steps of: setting signal attenuation of a first unit; setting signal attenuation of a second unit; setting signal attenuation of a third unit; and setting signal attenuation of a fourth unit, wherein the first unit, the second, the third unit and the fourth unit are connected in series, and wherein selecting signal attenuation of a unit comprises selecting one of no attenuation, a first signal attenuation and a second signal attenuation thereof.

### BRIEF DESCRIPTION OF THE DRAWINGS

For a more complete understanding of the disclosure, reference is made to the following description and accompanying drawings, in which:

FIG. 1A is a schematic of the layout of an embodiment of a single-pole two-throw (SP2T) switch device;

FIG. 1B is a schematic of the layout of a single-pole three-throw (SP3T) switch device;

FIG. 2A is an illustration of an optical micrograph of the SP2T switch device of FIG. 1A;

FIG. 2B is an illustration of an optical micrograph of the SP3T switch device of FIG. 1B;

FIG. 3 is an illustration of an optical micrograph of an embodiment of a SP3T switch device;

FIG. 4 are graphs illustrating measured and simulated radio frequency performance of an embodiment of a SP3T switch device;

FIG. 5 is a schematic of a layout of an embodiment of a SP3T switch device connected to an input and three lines including two attenuator bits;

FIG. 6 is a schematic of an embodiment of a unit;

FIG. 7 is a schematic of a portion of an embodiment of a unit;

FIG. 8 is a schematic of an embodiment of a module;

FIG. 9 is a table illustrating signal attenuation levels of the module of FIG. 8;

FIG. 10A to FIG. 10F are graphs illustrating attenuation responses and return losses of portions of the module of FIG. 8;

FIG. 11 are graphs illustrating attenuation levels of the module of FIG. 8;

FIG. 12 are graphs illustrating minimum and maximum signal-attenuation ranges of the module of FIG. 8;

FIG. 13 is a schematic illustrating the physical layout of a portion of a module;

FIG. 14 is a schematic illustrating a chip layout of a module;

FIG. 15 is an illustration of an optical micrograph of bridged-T resistor networks; and

FIG. 16 is a flowchart illustrating a method for operating a module.

### DETAILED DESCRIPTION

Although embodiments have been described above with reference to the accompanying drawings, those of skill in the art will appreciate that variations and modifications may be made without departing from the scope thereof as defined by the appended claims.

The present disclosure provide modules and methods for attenuators suitable for applications including modern communications systems, requiring high linearity, low power consumption, and low temperature dependency. Some embodiments of the modules and methods disclosed herein provide attenuators that preserve signal integrity while controlling the signal power. Some embodiments of the modules and methods disclosed herein have a high dynamic range, low insertion loss, wide attenuation range, and wide frequency bandwidth. Some of the embodiments of the modules and methods disclosed herein are suitable for operation in the mid-band (c-band) for fifth-generation (5G) communications.

In some embodiments disclosed herein, modules and methods provides radio frequency (RF) attenuation tuning with an analog type tuning approach with digital control. In some embodiments disclosed herein, modules and methods provides a digital attenuator with 512 incremental steps of ±0.05 decibel (dB) and a total attenuation range of 26.52 dB.

Some embodiments of the modules and methods disclosed herein provide a digital attenuator comprising bridged-T network fixed-attenuator bits and fixed phase-change elements in a crystalline state. In some embodiments disclosed herein, the phase-change elements comprise single-pole, three-throw (SP3T), monolithically integrated to switch fixed crystalline phase-change elements arranged in a cascade and bridged-T networks to provide high precision attenuation tuning.

In some embodiments disclosed herein, the phase-change elements are devices comprised of chalcogenide phase-change material (PCM) such as germanium telluride (GeTe). The PCM devices such as the GeTe-based PCM devices provide suitable performance for RF and millimeter wave (mmWave) applications. PCM-based switches may be monolithically and/or heterogeneously integrated with various other technologies without any need for packaging, which makes these devices affordable and attractive for implementation as reconfigurable RF components. As a result of GeTe exhibiting non-volatile properties, PCM devices provide latching characteristics that do not require a constant steady-state direct current (DC) power to hold switch states. The use of a non-volatile technology in RF reconfigurable attenuators greatly reduces the consumption of static DC power. Further, such technologies greatly reduce chip and/or die size footprints as single-pole single-throw (SPST) switches and routing paths may be densely packed. Multi-port switches (such as SP3T and single-pole two-throw (SP2T) switches) and bridged-T networks in fixed attenuators may be monolithically integrated in multi-stage tuning configurations. Further, GeTe material in crystalline state may be used to provide intentional loss in signal paths for reducing step sizes between attenuator stages.

RF PCM-based SPST switches discussed herein provide favourable characteristics as they relate to broadband operation frequency, highly miniaturized chip/die size, low insertion loss, low control voltage requirement, latching operation, improved power handling capability, and reasonable linearity and switching time. Based on suitable RF switch aspects, appropriate compact multi-port RF PCM-based SP2T and SP3T switches may be provided.

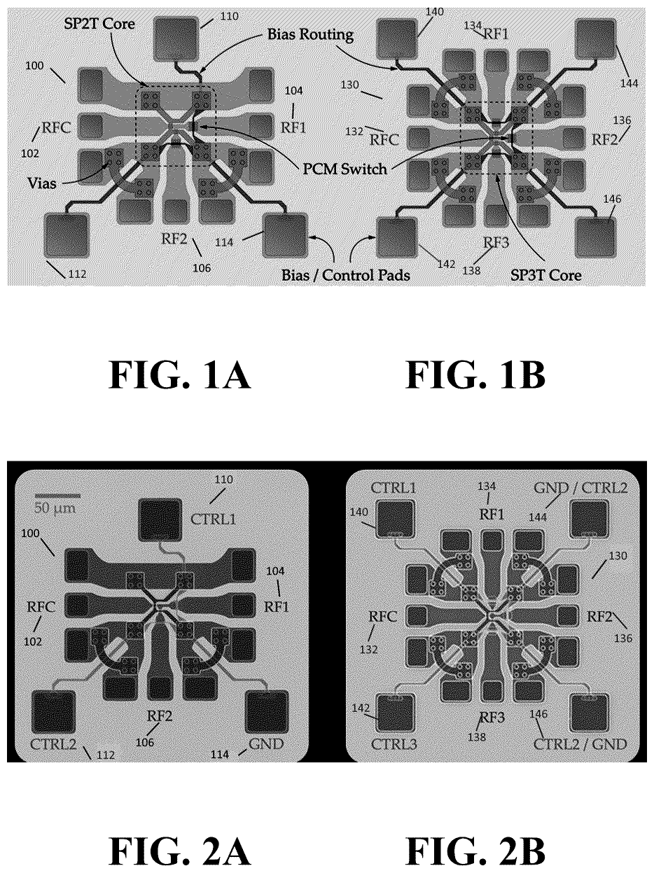

Multi-port switches may have similar junction dimensions as those of the SPST switches developed using microfabrication processes. FIG. 1A illustrates a layout of a SP2T switch 100 and FIG. 1B illustrates a layout of a SP3T switch 130 according to some embodiments disclosed herein. Any RF device with more than two RF ports in a coplanar waveguide (CPW) configuration may require interconnection of RF ground connections. In some embodiments disclosed herein, RF grounds can be connected in the microfabrication processes. The distance between metal layers and the dielectric constant therebetween can cause large parasitic capacitances, which may result in impedance mismatches to a RF signal line, which may be around 5052, for example. In some embodiments disclosed herein, the SP2T and SP3T switch cores have similar ground connections and the RF signal path therein are optimized, as further described herein, to maintain characteristic impedances. Optimizing impedance and loss of overlapping metal layers is especially important especially for mmWave devices, as parasitic capacitance may block signal flow if not properly addressed during design. FIG. 2A illustrates an optical micrograph of a SP2T switch and FIG. 2B illustrates an optical micrograph of a SP3T switch 130 according to some embodiments disclosed herein.

Referring to FIG. 1A and FIG. 2A, in some embodiments disclosed herein, an RF PCM-based SP2T switch 100 has three ports, namely RFC 102, RF1 104, and RF2 106. RFC 102 is a common RF input port while RF1 104 and RF2 106 are two RF output ports. In some embodiments disclosed herein, a SP2T switch 100 comprises two RF PCM-based switches. Referring to FIG. 2A, CTRL1 110, CTRL2 112 and GND 112 are control signals. Providing an actuation pulse (for example, an amorphous pulse or a crystalline pulse) between CTRL1 110 and GND 110 actuates the switch between RFC 102 and RF1 104 to provide a signal path from input RFC 102 to output RF1 104. Providing an actuation pulse between CTRL2 112 and GND 114 actuates the switch between RFC 102 and RF2 106 to provide a signal path between RFC 102 and RF2 106. As a result of the compact dimensions of RF PCM-based switches, the switches may be placed as close to a T-junction or T-shaped RF intersections as practicable to minimize any reflected RF signals from the non-connected port.

In some embodiments disclosed herein, a PCM-based SP3T switch 130 is shown in FIG. 2B which operates similarly to the RF PCM-based SP2T switch 100, having RFC 132, RF1 134 and RF2 136 with an additional RF3 138 output port. In some embodiments disclosed herein, RF PCM-based switches are latching switches, meaning that they are non-volatile switches that they may remain in the connected state for a relatively long time without continuous application of the corresponding control signal until another control signal triggers its disconnection, which allows the sharing of control and bias pads. To minimize the number of control pads used, in some embodiments disclosed herein, a SP3T switch 130 is designed using only four control pads, namely CTRL1 140, CTRL3 142, and two shared pads GND/CTRL2 144 and CTRL2/GND 146. Providing an actuation pulse between CTRL1 140 and GND/CTRL2 144 (where GND/CTRL2 144 acts as a ground terminal) actuates the switch between RFC 132 and RF1 134 to provide a signal path from input RFC 132 to output RF1 134. Providing an actuation pulse between GND/CTRL2 144 and CTRL2/GND 146 actuates the switch between RFC 132 and RF2 136 to provide a signal path from input RFC 132 to output RF2 136. Providing an actuation pulse between CTRL3 142 and CTRL2/GND 146 (where GND/CTRL2 146 acts as a ground terminal) actuates the switch between RFC 132 and RF3 138 to provide a signal path from input RFC 132 to output RF3 138. In some embodiments disclosed herein, the PCM-based SP3T switch 130 may comprise one or more dummy pads of switches that are not connected.

In some embodiments disclosed herein, a RF PCM-based switch junction (or a PCM-based SPST switch core) in SPST switches are about 20 μm×20 μm in size while the overall size of the SPST switch is about 500 μm×400 μm. The additional area of the SPST switch other than the switch junction is for RF ports and bias pads. RF CPW port sizes can be designed to meet a variety of purposes, including to meet the requirements of a ground-signal-ground (GSG) probe pitch size. GSG probes are manufactured with pitch sizes varying from about 50 μm to 250 μm, thus the overall device size may depend largely on the desired probe pitch size. Overall device sizes are determined including all RF ports and bias pads (which depends on GSG probe pitches). If a core is smaller in size than a port size, it not only increases the overall device size, but also introduces additional RF signal transmission loss due to length and tapering of a RF signal path. In embodiments disclosed herein, a RF SPST switch is designed to accommodate GSG probe pitches between about 100 μm to 250 μm.

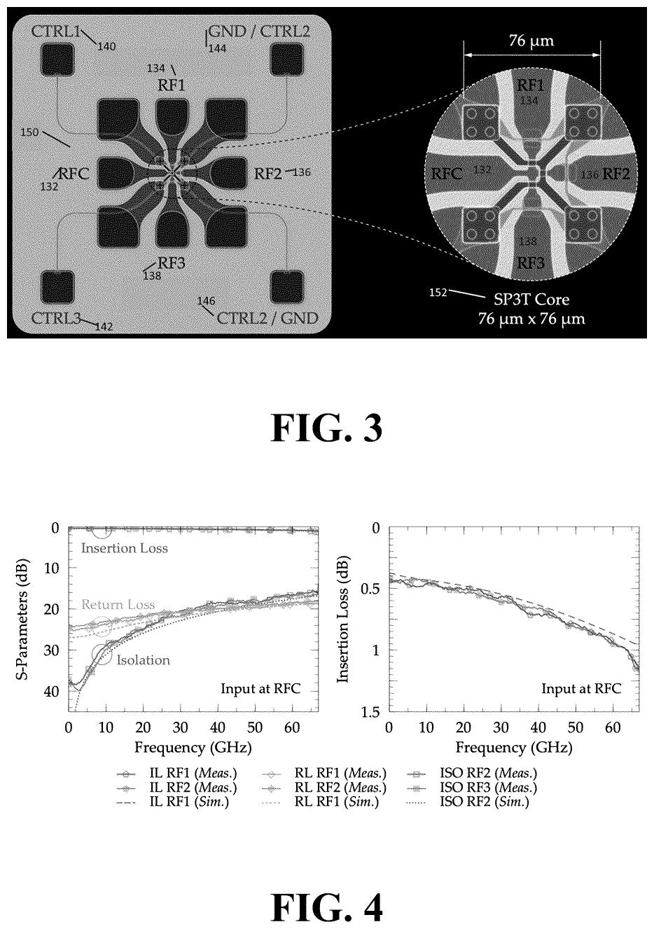

FIG. 3 illustrates an optical micrograph of an embodiment of a RF PCM-based SP3T switch 150 with a larger port size. Switch functionality and performance are substantially identical to the SP3T switch 130 illustrated in FIG. 1B and FIG. 2B with a different RF port size to accommodate larger probe pitches (for example, about 150 μm). Referring to FIG. 3, a SP3T core 152 is illustrated with an inset having dimensions about 76 μm×76 μm, which is highly miniaturized and may be monolithically integrated into any RF device. The overall device area of the SP3T switch 130 in FIG. 2A and the SP3T switch 130 in FIG. 2B is less than about 300 μm×300 μm, while the overall device size of the SP3T switch 150 in FIG. 3 is about 600 μm×600 μm.

FIG. 4 illustrates simulated and measured performance of RF parameters of an embodiment of a SP3T switch. Due to similar and symmetrical device core structures, the performance of an embodiment of a SP2T switch is substantially identical to the SP3T switch. Referring to FIG. 4, the SP3T switch showed lower than 1.2 dB insertion loss and better than 16 dB isolation. Return loss is greater than 18 dB over the frequency range. Measured parameters match closely with electromagnetic field (EM) simulations as all material parameters required for EM simulations were taken by measuring various test structures of the switch. Measurements of the switch had greater than 41 dBm input third-order intercept point (IIP3) and was able to handle at least 3.5 W continuous wave (CW) power (not including self-actuating concerns) and may be improved by modifying the RF PCM-based switch junction dimensions.

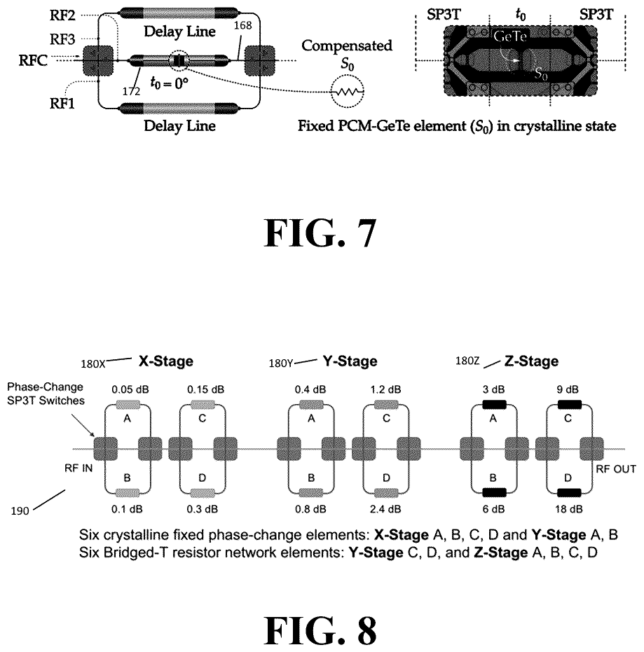

FIG. 6 illustrates four SP3T switches arranged in series with a first pair of SP3T switches defining three paths, t₀, t₁ and t₂, and a second pair of SP3T switches defining three paths, t₀, t₃ and t₄. FIG. 7 illustrates S3PT switches arranged in a similar topology as a pair of SP3T switches where the t₀ path is optimized using the compensated S₀. In some embodiments, this is achieving by adjusting the width and length of GeTe element of the t₀ section.

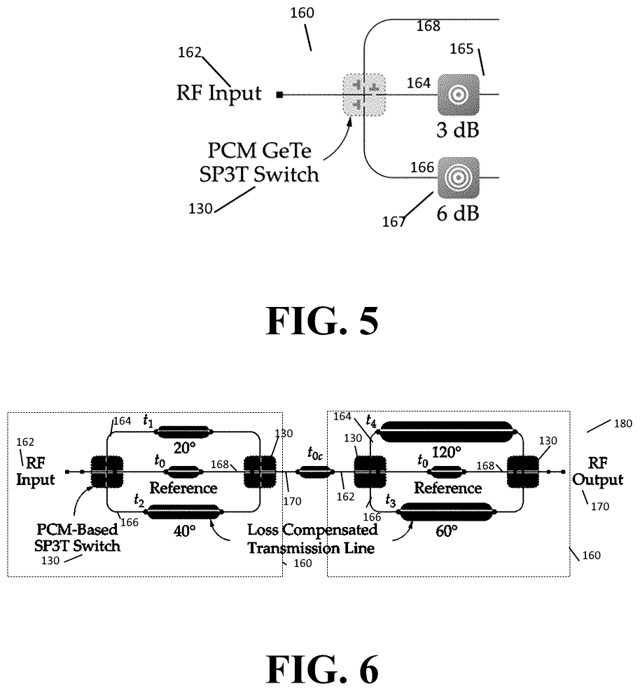

In some embodiments disclosed herein, unit 160 comprises a unit input 162 and a unit output. The unit 160 comprises a first, a second, and a third selectable conductive path 164, 166, and 168, where the first path 164 comprises a first attenuation element 165 and the second path 166 comprises a second attenuation element 167. The third path 168 may be optimized as described above relating to the t₀ path of FIG. 7. The unit 160 comprises a switching element for selectably connecting the unit input 162 to the unit output via one of the three selectable conductive paths 164, 166, and 168. Referring to FIG. 5, in an embodiment, the switching element is a SP3T switch 130 connected to the RF input or unit input 162 and three selectable conductive paths 164, 166, and 168, wherein the first path 164 has a first attention element 165 with an attenuation of 3 dB and the second path 166 has a second attenuation element 167 with an attenuation of 6 dB. In some embodiments disclosed herein, the unit 160 further comprises a second switching element for connecting the three selectable conductive paths 164, 166, and 168 to the unit output.

Referring to FIG. 6, a portion 180 comprises two units 160 connected in series. Referring to FIG. 6, the unit output 170 of the first unit 160 is connected to the unit input 162 of the second unit 160. In some embodiments disclosed herein, a module 190 comprises two or more portions 180 connected in series. Referring to FIG. 8, a module 190 comprises three portions 180 or stages: a first stage (X-Stage) 180X, a second stage (Y-Stage) 180Y and a third stage (Z-Stage) 180Z.

In some embodiments, the module 180 comprises a third unit wherein the unit output 170 of the second unit 160 is connected to the unit input 162 of the third unit. In some embodiments, the module 180 comprises four or more units 160 following the same configuration pattern.

In some embodiments, for each unit 160, the signal attenuation of the first attenuation element 165 is greater than the signal attenuation of the second attenuation element 167. Further, in some embodiments, for each portion 180, the signal attenuation of the first attenuation element 165 of the second unit 160 is greater than the signal attenuation of the second attenuation element 167 of the first unit 160. Alternatively, in some embodiments, for each portion 180, the signal attenuation of the first attenuation element 165 of the first unit 160 is greater than the signal attenuation of the second attenuation element 167 of the second unit 160.

In some embodiments, the signal attenuation of the first attenuation element 165 of the first unit 160 of the second portion 180 is greater than the signal attenuation of the second attenuation element 167 of the second unit 180 of the first portion 180. In some embodiments, the order of the first portion 180 and second portion 180 is not important. Specifically, in some alternative embodiments, the signal attenuation of the first attenuation element 165 of the first unit 160 of the first portion 180 is greater than the signal attenuation of the second attenuation element 167 of the second unit of the second portion 180.

In some embodiments, the module 190 comprises a third portion 180 connected in series. In some embodiments, the signal attenuation of the attenuation elements 165 and 167 of the third portion 180 may be higher or lower than the signal attenuation of the attenuation elements 165 and 167 of the first and second portions 180.

While the relative ordering of the portions 180 is not important, a module 190 having portions 180 with attenuation elements 165 and 167 having different signal attenuation provides a system with a broad range and fine tuning. Specifically, portions 180 with attenuation elements 165 and 167 with greater signal attenuation provides a broader range of signal attenuation while portions 180 with attenuation elements 165 and 167 with smaller signal attenuation provides finer tuning of signal attenuation provided by the module 190.

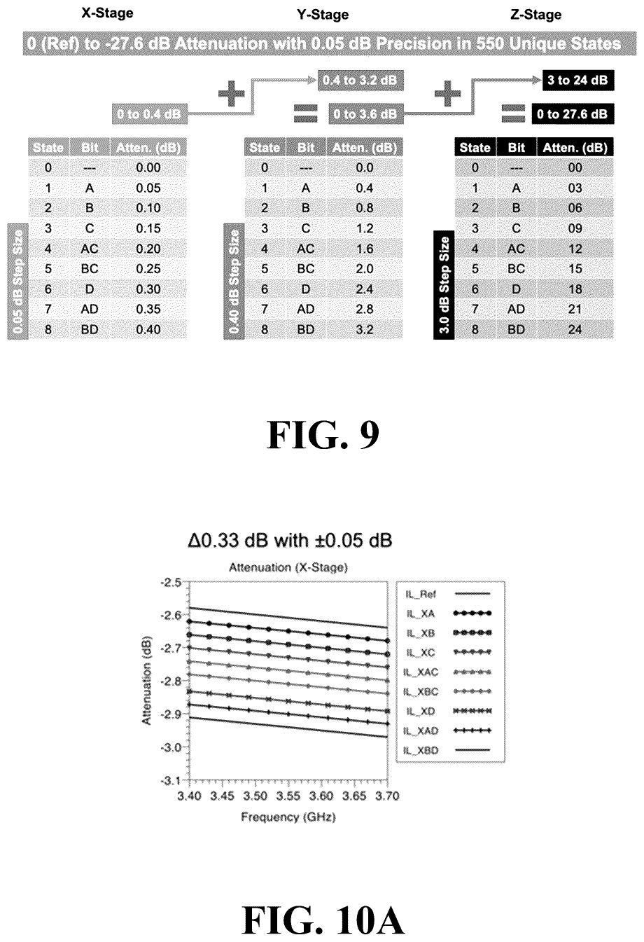

In some embodiments disclosed herein, implementations of a three-stage tuning approach including a coarse stage, a fine stage, and an extra fine stage are provided to improve the attenuation precision steps. Referring to FIG. 8, in an embodiment, a first portion (X-Stage) 180X comprises attenuation elements providing the lowest signal attenuation, a second portion (Y-Stage) 180Y comprises attenuation elements providing intermediate signal attenuation, and a third portion (Z-Stage) 180Z comprises attenuation elements providing the highest signal attenuation elements. In some embodiments, the module 190 comprises any combination of two or more of the first portion 180X, second portion 180Y and third portion 180Z. In an embodiment, the first attenuation element 165 of the first unit 160 of the first portion 180X is 0.05 dB (A of X-Stage), the second attenuation element 167 of the first unit 160 of the first portion 180X is 0.1 dB (B of X-Stage), the first attenuation element 165 of the second unit 160 of the first portion 180X is 0.15 dB (C of X-Stage), the second attenuation element 167 of the second unit 160 of the first portion 180X is 0.3 dB (D of X-Stage), the first attenuation element 165 of the first unit 160 of the second portion 180Y is 0.4 dB (A of Y-Stage), the second attenuation element 167 of the first unit 160 of the second portion 180Y is 0.8 dB (B of Y-Stage), the first attenuation element 165 of the second unit 160 of the second portion 180Y is 1.2 dB (C of Y-Stage), the second attenuation element 167 of the second unit 160 of the second portion 180Y is 2.4 dB (D of Y-Stage), the first attenuation element 165 of the first unit 160 of the third portion 180Z is 3 dB (A of Z-Stage), the second attenuation element 167 of the first unit 160 of the third portion 180Z is 6 dB (B of Z-Stage), the first attenuation element 165 of the second unit 160 of the third portion 180Z is 9 dB (C of Z-Stage), and the second attenuation element 165 of the second unit 160 of the third portion 180Z is 18 dB (D of Z-Stage). This embodiment provides 26.52 dB of signal attenuation with ±0.05 dB precision in 512 steps. In this embodiment, 12 phase-change SP3T switches are arranged back-to-back in a cascaded chain forming three portions 180 or stages. In some embodiments, the attenuation elements 165 and 167 are fixed phase-change thin-film crystalline elements with increasing resistance to achieve certain attenuation level. Cascading the portions or stages in such an arrangement analog style tuning from a digitally reconfigurable device. FIG. 9 illustrates the various signal attenuation levels or states for each portion 180 or stage, wherein the signal attenuation level of the portions 180 are added together as the portions 180 are connected in series, as follows:

| Portion or Stage | State | Bit | Attenuation |
|---|---|---|---|
| X | 0 | — | 0.00 |
| X | 1 | A | 0.05 |
| X | 2 | B | 0.10 |
| X | 3 | C | 0.15 |
| X | 4 | AC | 0.20 |
| X | 5 | BC | 0.25 |
| X | 6 | D | 0.30 |
| X | 7 | AD | 0.35 |
| X | 8 | BD | 0.40 |
| Y | 0 | — | 0.0 |
| Y | 1 | A | 0.4 |
| Y | 2 | B | 0.8 |
| Y | 3 | C | 1.2 |
| Y | 4 | AC | 1.6 |
| Y | 5 | BC | 2.0 |
| Y | 6 | D | 2.4 |
| Y | 7 | AD | 2.8 |
| Y | 8 | BD | 3.2 |
| Z | 0 | — | 0 |
| Z | 1 | A | 3 |
| Z | 2 | B | 6 |
| Z | 3 | C | 9 |
| Z | 4 | AC | 12 |
| Z | 5 | BC | 15 |
| Z | 6 | D | 18 |
| Z | 7 | AD | 21 |
| Z | 8 | BD | 24 |

In some embodiments, the module 190 comprises one or more amplifiers located between the units 160 and/or the portions 180. In some embodiments, the module 190 comprises one or more matching networks located between the units 160 and/or the portions.

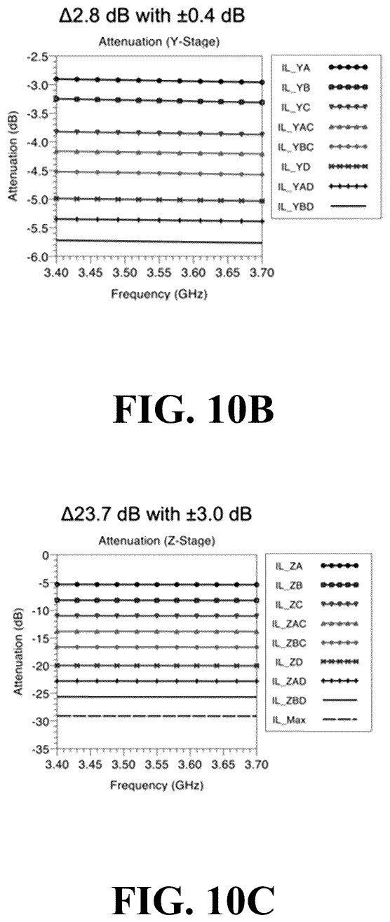

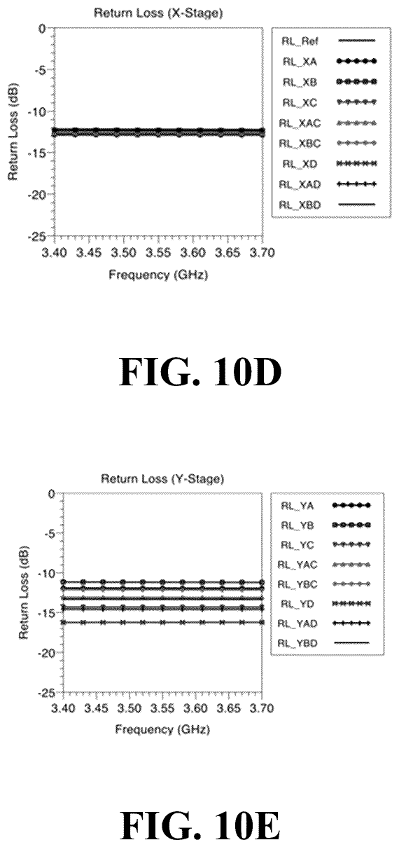

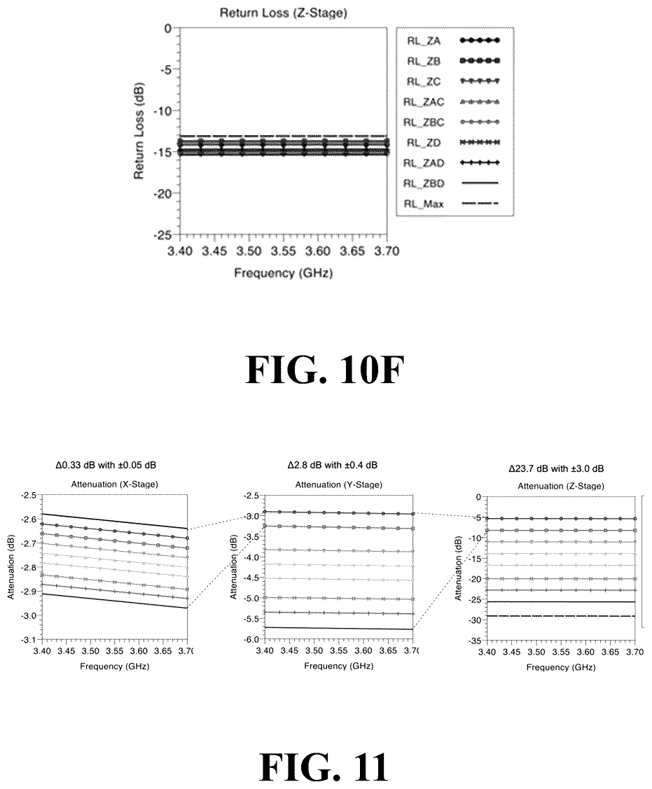

FIG. 10A to FIG. 10F illustrate attenuation responses of the first portion or stage (X-Stage) 180X, the second portion or stage (Y-Stage) 180Y, and the third portion or stage (Z-Stage) 180Z. More specifically, FIG. 10A illustrates the attenuation levels of the first stage 180X, FIG. 10B illustrates the return losses of the first stage 180X, FIG. 10C illustrates the attenuation levels of the second stage 180Y, FIG. 10D illustrates the return losses of the second stage 180Y, FIG. 10E illustrates the attenuation levels of the third stage 180Z, and FIG. 10F illustrates the return losses of the third stage 180Z.

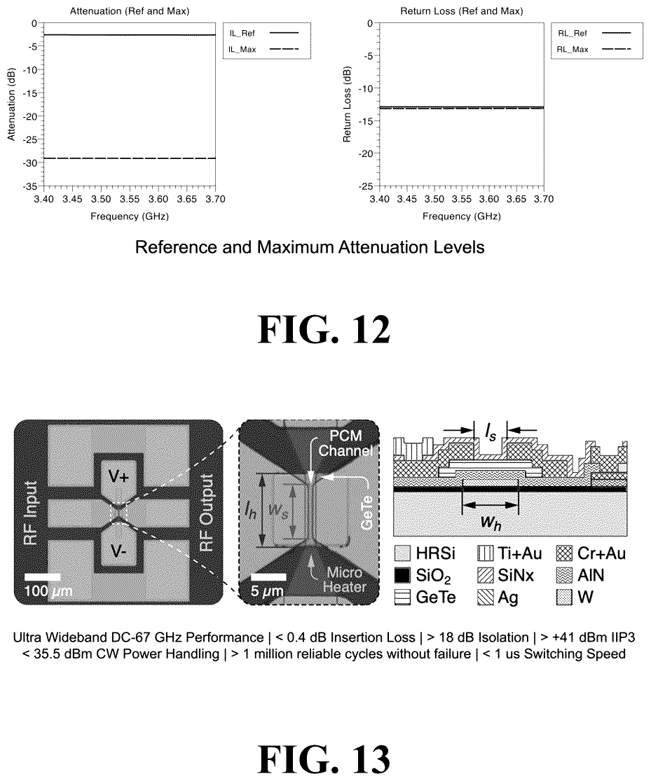

FIG. 11 illustrates the attenuation levels of the first stage 180X, the second stage 180Y, and the third stage 180Z, including illustrating that the range of the first stage 180X is within one of the increments of the second stage 180Y and the range of the second stage 180Y is within one of the increments of the third stage 180Z. FIG. 12 illustrates the minimum and maximum signal attenuation ranges.

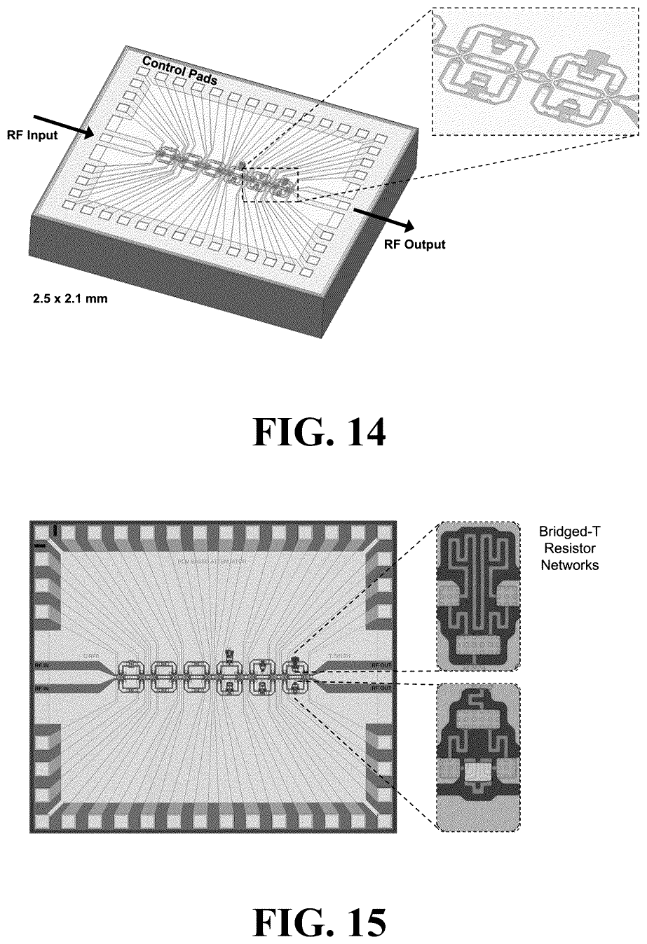

FIG. 13 illustrates the physical layout of a phase-change element and a cross-section thereof including composite layers comprising high resistivity silicon wafer (HRSi), silicon oxide (SiO₂), germanium telluride (GeTe), titanium and gold (Ti+Au), silicon nitride (SiNx), silver (Ag), chromium and gold (Cr+Au), alumina nitride (AlN), and tungsten (W). FIG. 14 is an illustration of an attenuator chip layout showing signal paths, control pads, and junctions. FIG. 15 is an illustration of an optical micrograph of a fabricated chip showing bridged-T resistor networks.

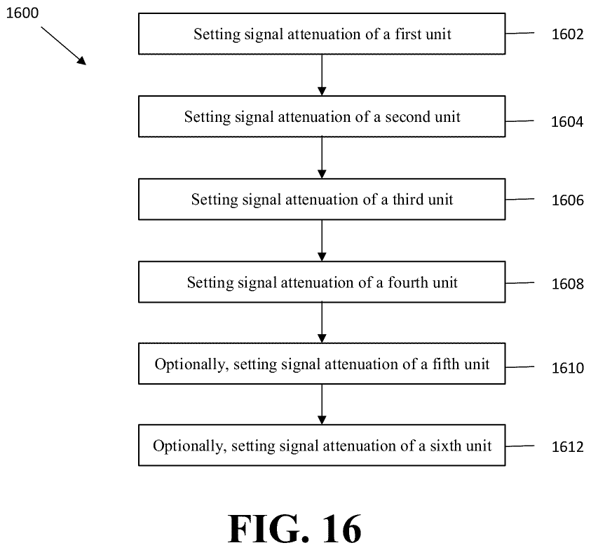

FIG. 16 is a flowchart showing the steps of a method 1600, according to one embodiment of the present disclosure. The method 1600 begins with setting signal attenuation of a first unit, (step 1602). At step 1604, signal attenuation of a second unit is set. At step 1606, signal attenuation of a third unit is set. At step 1608, signal attenuation of a fourth unit is set. Optionally, at step 1610, signal attenuation of a fifth unit is set. Optionally, at step 1612, signal attenuation of a sixth unit is set.

1. A module comprising two portions, each portion comprising a first unit and a second unit, each of the units comprising:
a unit input;
a unit output;
a first, a second, and a third selectable conductive path, the first path comprising a first attenuation element and the second path comprising a second attenuation element; and
an input switching element for selectably connecting the unit input to the unit output via one of the three selectable conductive paths;
wherein the unit output of the first unit of each portion is connected to the unit input of the second unit thereof; and
wherein the unit output of the second unit of the first portion is connected to the unit input of the first unit of the second portion.

2. The module of claim 1, wherein for each unit, signal attenuation of the second attenuation element is greater than signal attenuation of the first attenuation element.

3. The module of claim 1, wherein for each portion, signal attenuation of the first attenuation element of the second unit is greater than signal attenuation of the second attenuation element of the first unit.

4. The module of claim 1, wherein signal attenuation of the first attenuation element of the first unit of the second portion is greater than signal attenuation of the second attenuation element of the second unit of the first portion.

5. The module of claim 1, wherein for each unit of a third portion of the module, signal attenuation of the second attenuation element is greater than signal attenuation of the first attenuation element.

6. The module of claim 1, wherein for a third portion of the module, signal attenuation of the first attenuation element of the second unit is greater than signal attenuation of the second attenuation element of the first unit.

7. The module of claim 1, wherein signal attenuation of the first attenuation element of the first unit of a third portion of the module is greater than signal attenuation of the second attenuation element of the second unit of the second portion.

8. The module of claim 1, comprising one or more additional portions, each additional portion comprising a first unit and a second unit, each of the units comprising:
a unit input;
a unit output;
a first, a second, and a third selectable conductive path, the first path comprising a first attenuation element and the second path comprising a second attenuation element; and
an input switching element for selectably connecting the unit input to the unit output via one of the three selectable conductive paths;
wherein the unit output of the first unit is connected to the unit input of the second unit.

9. The module of claim 1, wherein each of the input switching elements is a single pole three-throw switch.

10. The module of claim 1, wherein each of the input switching elements comprises one or more of: a phase-change material and four control pads and two shared pads for control and biasing.

11. The module of claim 10, wherein the phase-change material comprises germanium telluride.

12. The module of claim 1, wherein each of the units further comprises an output switching element connected to the three selectable conductive paths and the unit output for selectably connecting one of the three selectable conductive paths and the unit output.

13. The module of claim 12, wherein each of the output switching elements is a single pole three-throw switch.

14. The module of claim 12, wherein each of the output switching elements comprises one or more of: a phase-change material and four control pads and two shared pads for control and biasing.

15. The module of claim 14, wherein the phase-change material comprises germanium telluride.

16. The module of claim 1, wherein each of the first attenuation elements and each of the second attenuation elements comprise bridged-T networks.

17. The module of claim 1, further comprising one or more of: one or more amplifiers between each of the portions and one or more matching networks between each of the portions.

18. A method comprising the steps of:
setting signal attenuation of a first unit;
setting signal attenuation of a second unit;
setting signal attenuation of a third unit; and
setting signal attenuation of a fourth unit,
wherein the first unit, the second, the third unit and the fourth unit are connected in series, and
wherein selecting signal attenuation of a unit comprises selecting one of no attenuation, a first signal attenuation and a second signal attenuation thereof.

19. The method of claim 18, wherein for each unit, the second signal attenuation is greater than the first signal attenuation.

20. The method of claim 18, further comprising the steps of:
setting signal attenuation of a fifth unit;
setting signal attenuation of a sixth unit;
wherein the fifth unit and the sixth unit are connected in series with the fourth unit, and
wherein selecting signal attenuation of a unit comprises selecting one of no attenuation, a first signal attenuation and a second signal attenuation thereof.
